(19) United States
(12) Patent Application Publication
(10) Pub. No.: US 2010/0112817 A1
(43) Pub. Date: May 6, 2010

(54) METHOD FOR FORMlNG PATTERN OF SEMICONDUCTOR DEVICE

(75) Inventor: Ki Lyoung LEE, Hwaseong-si (KR)

Correspondence Address: AMPACC Law Group, 3500 188th Street S.W., Suite 103, Lynnwood, WA, 98037, US

(73) Assignee: Hynix Semiconductor Inc., Gyeonggi-do (KR)

(21) Appl. No.: 12/490,105

(22) Filed: Jun. 23, 2009

(30) Foreign Application Priority Data
Nov. 3, 2008 (KR) 10-2008-0108450

(51) Int. Cl. H01L 21/311

(52) U.S. Cl. 438/694; 257/E21.249

(57) ABSTRACT

A method for forming a pattern of a semiconductor device using a spacer patterning process comprises coating a developable antireflection film over a substrate including a spacer pattern, coating a photoresist film over the antireflection film, and patterning the antireflection film and the photoresist film by an exposing and developing process to form an etching mask pattern. The etching mask pattern has an excellent profile. When a lower underlying layer is etched using the etching mask pattern, a sufficient etching margin can be secured, thereby obtaining a reliable semiconductor device.

### CROSS-REFERENCE TO RELATED APPLICATION

Priority to Korean patent application number 10-2008-108450, filed on Nov. 3, 2008, the whole disclosure of which is incorporated by reference, is claimed.

### BACKGROUND OF THE INVENTION

The invention generally relates to a method for forming a semiconductor device pattern, and more specifically, to a method for forming a semiconductor device, e.g., NAND flash memory device pattern, using a spacer patterning technology.

Recently, semiconductor technology has rapidly developed in order to store the ever increasing amount of information; quickly process or transmit information; and construct a simpler information communication network in line with the 21^{th} century information communication society.

Particularly, due to rapid popularization of information media such as computers, research on development of process equipment or process techniques for manufacturing a semiconductor device has been made. The goal of the research has been to produce smaller semiconductor components with a larger capacity and a low manufacturing cost without degrading electric characteristics.

In a semiconductor device, operation speed and device performance increases as a critical dimension of the pattern is made smaller. As a result, it is important to control a critical dimension of the pattern as semiconductor devices become smaller.

However, it is difficult to form a line/space (L/S) pattern using a one-time exposure process which has a critical dimension of less than 40 nm. This is due to a resolution limit of an ArF exposer which is employed for a current semiconductor device pattern forming process. Particularly, it is difficult to form a L/S pattern of less than 30 nm using a high index fluid and an exposer with a high numeral aperture. In order to obtain a smaller size of a L/S pattern, an exposure light source with a short wavelength [e.g., Extreme Ultra Violet (EUV) (13.4 nm)] has been developed along with an exposer and a resist suitable for such a light source. However, it is still insufficient to catch up with the fast growing manufacturing process needs of semiconductor devices.

As a result, a method of decreasing a K1 factor of the conventional exposer is suggested to improve a resolution of a photolithography process and increase a process margin. This has led to a development of a double patterning technology with an improved resolution.

The double patterning technology is carried out by a double exposing and etching technology or a spacer patterning technology.

The double exposing and etching technology includes a positive method and a negative method. The positive method includes forming a first pattern having a pitch twice larger than that of a desired pattern, forming a second pattern having a pitch twice larger than that of a desired pattern disposed between the first patterns, and forming the desired pattern using the first and second patterns as etching masks. The negative method includes forming a first pattern by using a first mask process, etching the first pattern to form a second pattern during a second mask process, and using the second pattern as an etching mask in a subsequent etching process.

The double exposing and etching technology enables formation of a pattern with a resolution higher than a single photolithography process because two kinds of masks are used. However, the double exposing and etching technology requires several additional processes which increases the manufacturing cost. Also, a mis-alignment may be generated due to an overlay accuracy error.

The spacer patterning technology is a self-alignment technology that uses a single mask process, thereby preventing mis-alignment. The spacer patterning technology may be performed by a positive method or a negative method.

As shown in FIG. 1, the positive method comprises forming an underlying layer 3, a first mask film 5, a second mask film 7 and a first photoresist pattern 8 over a semiconductor substrate 1; etching the second mask film 7 using the first photoresist pattern 8 as an etching mask to form a second mask pattern 7-1; forming a spacer 9 at sidewalls of the second mask pattern 7-1; removing the second mask pattern 7-1 to form a spacer pattern 9-1; and etching the first mask film using the spacer pattern 9-1 as an etching mask to form a first mask pattern 5-1.

However, the spacer patterning technology requires additional processes of forming a spacer pattern; forming a pad pattern to connect a contact; and performing the cutting mask process for separating a line end region of the spacer pattern before etching a lower mask film. This makes the process steps for the spacer patterning technology complicated. Moreover, since an asymmetrical spacer pattern is used as an etching mask, etching process conditions will change at different chip locations, so that it is not easy to control a critical dimension of the lower underlying pattern.

FIGS. 2a to 2h are diagrams illustrating a conventional method for forming a control gate pattern of a flash memory device using the conventional spacer patterning technology.

Referring to FIG. 2a, an underlying layer 11 is formed over a substrate including a device isolation film (ISO) (not shown). The underlying layer 11 includes a dielectric film (not shown) (e.g., oxide film-nitride film-oxide film), a gate polysilicon layer (not shown), a tungsten conductive layer (not shown), a capping oxide film (not shown) and a gate mask film (not shown).

A polysilicon layer 13, a nitride film 15 (i.e., a first mask film), an oxide film 17 (i.e., a second mask film), and a polysilicon layer 19 (i.e., a third mask film) are sequentially deposited over the underlying layer 11.

An antireflection film (not shown) and a photoresist film (not shown) are coated over the polysilicon layer 19. A first photolithography process is performed on the photoresist film to form a first photoresist pattern 21.

Referring to FIG. 2b, the antireflection film (not shown) and the polysilicon layer 19 are etched using the first photoresist pattern 21 as an etching mask to form an antireflection film pattern (not shown) and the polysilicon layer pattern (not shown). The oxide film 17 functioning as a second mask film is etched using the first photoresist pattern 21, an antireflection pattern (not shown) and a polysilicon pattern (not shown) as etching masks, thereby obtaining an oxide pattern 17-1.

Referring to FIG. 2c, a polysilicon film (not shown) is deposited over the substrate including the oxide pattern 17-1. The polysilicon film (not shown) is etched to form a spacer 23 at sidewalls of the oxide pattern 17-1.

Referring to FIG. 2d, the oxide pattern 17-1 is removed to form a spacer pattern 23-1. The spacer pattern 23-1, from a plan view, has an end portion connected with a “c” shape (see B in FIG. 2e).

Referring to FIG. 2e, an antireflection film (not shown) and a second photoresist film (not shown) are coated over the resulting structure including the spacer pattern 23-1. A second photolithography process is performed on the antireflection film and a second photoresist film to form an antireflection film pattern (not shown) and a second photoresist pattern 25. The second photoresist pattern 25 will be used for a pad pattern. As shown in (B) of FIG. 2e, the second photoresist pattern 25 is formed in a peripheral region of the spacer pattern 23-1. The spacer pattern can be used in the creation of a Source Selection Line (SSL), a Drain Selection Line (DSL) or interconnections.

When the second photoresist pattern 25 for a pad pattern is formed, a SSL (not shown) and DSL (not shown) are formed together. A SSL and a DSL are used for a turn-on of a channel.

In the case of a control gate of a general NAND flash memory device, a select transistor is disposed at both ends of 16 or 32 word lines (strings or cells). The SSL is connected to a source contact through a metal line, and the DSL is connected to a drain contact through a metal line. The SSL and the DSL have a larger critical dimension than that of the word line which is determined by the thickness of the spacer. Since the SSL and the DSL are disposed at both ends of the word line, defocus worsens at the edges to degrade an aerial image (i.e., a margin of the depth of focus is relatively insufficient rather than that of the word line). As a result, the lines for the SSL or the DSL may be formed connected when the second photoresist pattern for a pad pattern is formed.

Referring to FIG. 2f, the polysilicon layer 13 and the nitride film 15 (i.e., the first mask film) are etched using the spacer pattern 23-1, the second photoresist pattern 25 and a photoresist pattern (not shown) for SSL or DSL as etching masks until the underlying layer 11 is exposed. This obtains mask patterns for a first word line or a pad pattern that include a stacked pattern of a polysilicon pattern 13-1 and a first mask nitride pattern 15-1. The mask pattern for a first word line has an end portion connected with a “⊂” shape corresponding to the spacer pattern shape.

Referring to FIG. 2g, a third photoresist film is coated over the substrate including the mask pattern for a first word line and the mask pattern (not shown) for a pad pattern. A third lithography process is performed to form a third photoresist pattern 27 that exposes the “c” shaped end portion of the mask pattern for a first word line as shown in (B) of FIG. 2g.

Referring to FIG. 2h, the “c” shaped end portion of the mask pattern for a first word line is etched away using the third photoresist pattern 27 as an etching mask, thereby obtaining a mask pattern for a second word line that includes a separated polysilicon pattern 13-2 and a first mask nitride pattern 15-2.

The lower underlying layer 11 is etched using the mask pattern for a second word line and the mask pattern for a pad pattern as etching masks, thereby forming a control gate pattern of a NAND flash memory.

Meanwhile, in the case of the conventional process, it is difficult to form a pad pattern in the peripheral region due to a structural problem of the spacer pattern having a large aspect ratio. For example, in order to form the photoresist pattern 25 for a pad pattern, the antireflection film 16 is coated over the substrate including the space pattern 23-1, and the photoresist film (not shown) is coated over the antireflection film 16 as shown in FIG. 3a. The photoresist film and the antireflection film 16 are patterned. However, the antireflection film having a non-uniform thickness is coated over the substrate due to the structure of the spacer pattern having a large aspect ratio. That is, when an antireflection film of about 430 Å is coated over the substrate, the uniform antireflection film of 430 Å is formed in the region where the spacer pattern does not exist, for example, the region where P/R pattern is expected to be formed, while the antireflection film of about 800 Å is filled in a space between the spacer patterns. As a result, the conventional process requires an additional step of etching the antireflection film 16 using the photoresist pattern 25 as an etching mask. This requires the photoresist pattern 25 as an etching mask to be formed thickly, thereby complicating the process step and making it difficult to secure a process margin. Moreover, the spacer pattern can be damaged by a hydrofluorocarbon (HFC) etching gas used in an etching process for removing the antireflection film filled between the spacer patterns and distorted spacer pattern (23-1) are formed. It is hard to obtain a desired underlying pattern using such distorted spacer pattern (23-1) as an etching mask.

As shown in FIG. 3b, if the process for coating the antireflection film in the bottom portion of the second photoresist film is not performed, notching is generated in the second photoresist pattern by reflection of an exposure source from the substrate during the second photolithography process. As a result, the second photoresist pattern has a degraded profile. Also, photoresist scum is generated between the spacer patterns, so that a subsequent process cannot be properly performed and the photoresist pattern is lifted by an adhesion defect between the substrate and the photoresist film.

### BRIEF SUMMARY OF THE INVENTION

Various embodiments of the disclosure are directed at providing a method for forming a pattern of a semiconductor device that comprises: coating an antireflection film that can be dissolved in an alkali developing solution over a substrate including a spacer pattern; coating a photoresist film; and performing an exposing and developing process to pattern the antireflection film and the photoresist film, thereby preventing profile degradation of the photoresist pattern, a lifting phenomenon of the photoresist pattern and scum generation of photoresist that remains between spacer patterns.

According to an embodiment of the present invention, a method for forming a pattern of a semiconductor device comprises: providing a substrate having a cell region and a peripheral circuit region, the substrate having an underlying layer overlying the cell region and the peripheral region; forming a first mask film over the underlying layer and forming a second mask film over the first mask film; patterning the second mask film to form a second mask pattern over the first mask film of the cell region; forming a spacer at sidewalls of the second mask pattern; removing the second mask pattern; coating an antireflection film, the antireflection film is formed using material that can be dissolved in an alkali developing solution, over the cell region and the peripheral circuit region; forming a photoresist film over the spacer and the antireflection film; etching the antireflection film and the photoresist film to form a stack pattern including an antireflection film pattern and a photoresist pattern on the peripheral circuit region; and etching the first mask film using the spacer of the cell region and the stack pattern of the peripheral circuit region as etching masks to form a first mask film pattern for word line on the cell region and a first mask film pattern for a pad pattern on the peripheral circuit region.

The photoresist is formed using material that generates acid when exposed to light.

Preferably, a pitch of the second mask pattern is twice wider than a device pitch.

The removing-the-second-mask-pattern includes performing a wet process using hydrofluoric acid (HF).

The antireflection film which is water-soluble in an alkali developing solution can be used to improve an adhesive force of the photoresist film to the substrate. In addition, by regulating a substrate reflectivity in a corresponding wavelength during the exposing process for forming a photoresist pattern, the antireflection film prevents the photoresist pattern from damages such as a waving wave phenomenon or a notching phenomenon.

The antireflection film is formed by (i) spin-coating an antireflection composition comprising a polymer for an antireflection film, a cross-linking agents and an organic solvent over the substrate; and (ii) baking the antireflection composition to form a cured antireflection film.

The polymer for an antireflection film comprises one or more compounds selected from the group consisting of an acrylate type polymer having a carboxyl group, a methacrylate type polymer having a carboxyl group and a norbornene type polymer having a carboxyl group so that the cross-linking can be broken in the presence of an acid. The cross-linking agents comprise one or more selected from the group consisting of an acrolein dimethylacetal, an acrolein diethylacetal and a melamine. And an organic solvent may be one or more selected from the group consisting of propyleneglycol methyletheracetate (PGMEA), propyleneglycol monomethylether (PGME), ethyl lactate, cyclohexanone, γ-butyrolactone, n-butanol, 2-butanol, 1-pentanol and 2-pentanol.

While the solvent is vaporized in the baking process, a cross-linkage is formed between polymers in the antireflection composition so that the antireflection film is cured. The baking process for curing the antireflection film is performed at 100˜250° C.

The cured antireflection film is not dissolved in an edge bead removal (EBR) solution or a photoresist solution but can be dissolved in an alkali developing solution for photoresist. The antireflection film is formed to have a thickness by 10˜30% to the whole thickness of the photoresist pattern. In addition, the antireflection film is coated higher in a region where a center region of the spacer pattern having a dense density than a region wherein an edge region of the spacer pattern having a low density.

The photolithography process on the antireflection film and the first photoresist film includes performing an exposing process using light sources such as KrF, ArF and EUV; and a developing process with an alkali aqueous solution. Preferably, the exposing process is performed by using an ArF immersion scanner with exposure energy of 100 mJ/cm².

Specifically, the antireflection film and the photoresist film are dissolved in the alkali aqueous solution during the developing process.

Preferably, in the exposing process for patterning the photoresist film, the inner cross-linkage of the antireflection film is disconnected by an acid generated from the photoresist film. As a result, since the antireflection film has a physical property that can be dissolved in a developing solution, the antireflection film is developed and removed in the developing process for photoresist patterning. Therefore, an additional etching process for removing the antireflection film is not performed like in the conventional method. The antireflection film disposed in the lower portion of the unexposed photoresist pattern is not removed but remains.

The process before or after coating the antireflection film is performed by a conventional spacer patterning technology.

As mentioned above, the method of the present invention comprises: coating an antireflection film that is water-soluble in an alkali developing solution before coating a photoresist film for forming a pad pattern; forming a photoresist film; and patterning the antireflection film and the photoresist film so that the antireflection film may be formed in a lower portion of an unexposed photoresist pattern, thereby improving an adhesive property of the photoresist pattern to the substrate and preventing a lifting phenomenon of the photoresist pattern.

Moreover, since the antireflection film that is water-soluble in an alkali developing solution is used, an additional etching process for removing the antireflection film is not required, thereby simplifying the process steps and preventing a damage of the spacer pattern and the photoresist pattern. Also, since the antireflection film is disposed in the lower portion of the photoresist film, a notching phenomenon of the photoresist pattern which is generated when the antireflection film is not used can be prevented, and a photoresist scum does not remain in a space between the spacer patterns. As a result, the method of the present invention can secure a process margin, thereby obtaining a reliable semiconductor device

### BRIEF DESCRIPTION OF THE DRAWINGS

FIG. 1 is a diagram illustrating a conventional spacer patterning process.

FIGS. 2a to 2h are diagrams illustrating a conventional method for forming a pattern of a semiconductor device including the conventional spacer patterning process.

FIG. 3a shows a cross-sectional diagram when an antireflection film is applied in the conventional spacer patterning process.

FIG. 3b shows a cross-sectional diagram when an antireflection film is not applied in the conventional spacer patterning process.

FIGS. 4a to 4j are diagrams illustrating a method for forming a pattern of a semiconductor according to an embodiment of the present invention.

FIG. 5 shows a profile photograph of the patterns obtained by the conventional method and the method according to an embodiment of the present invention.

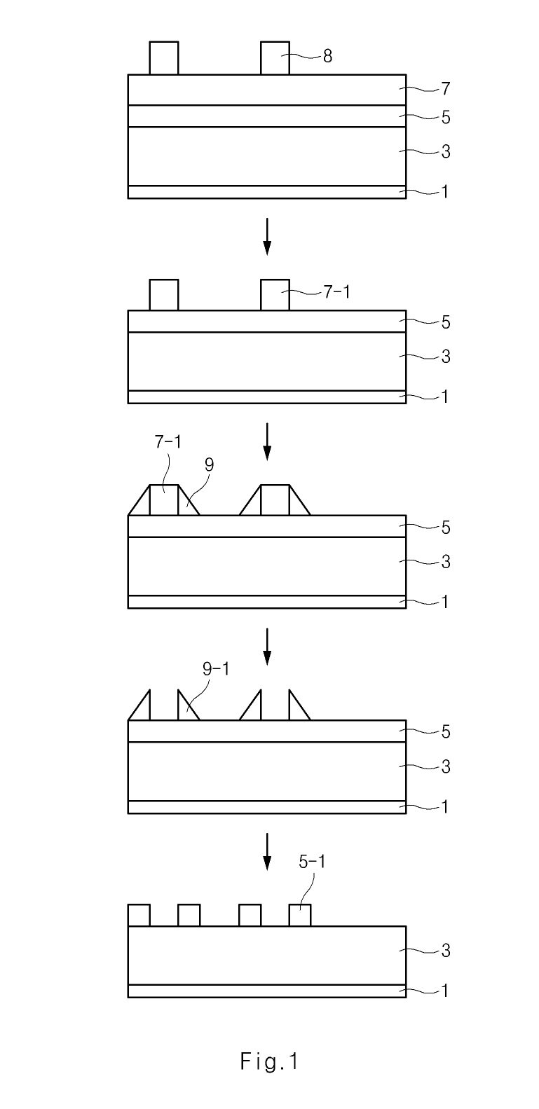

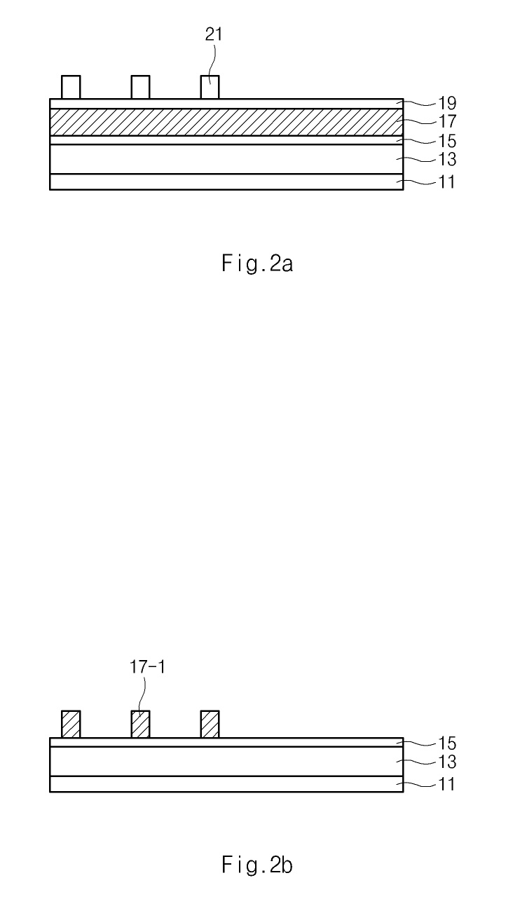

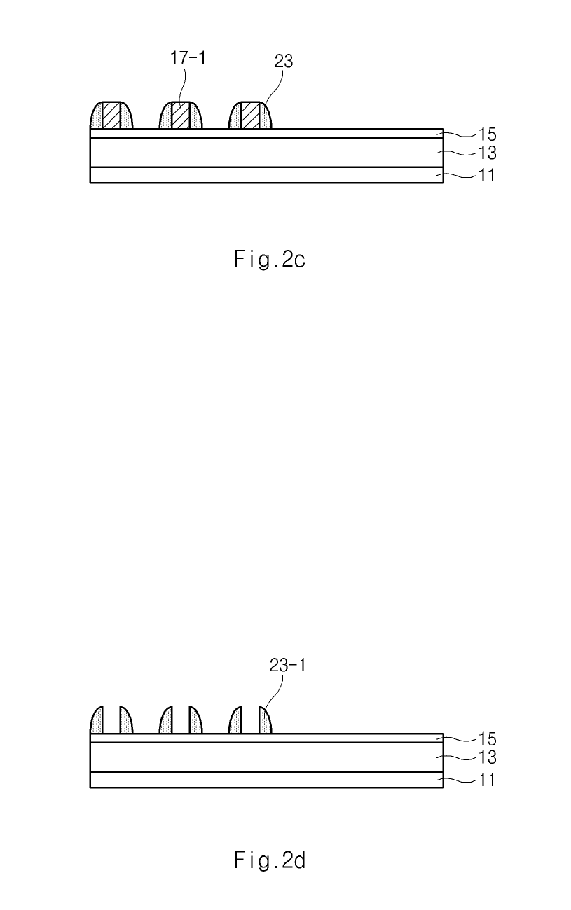

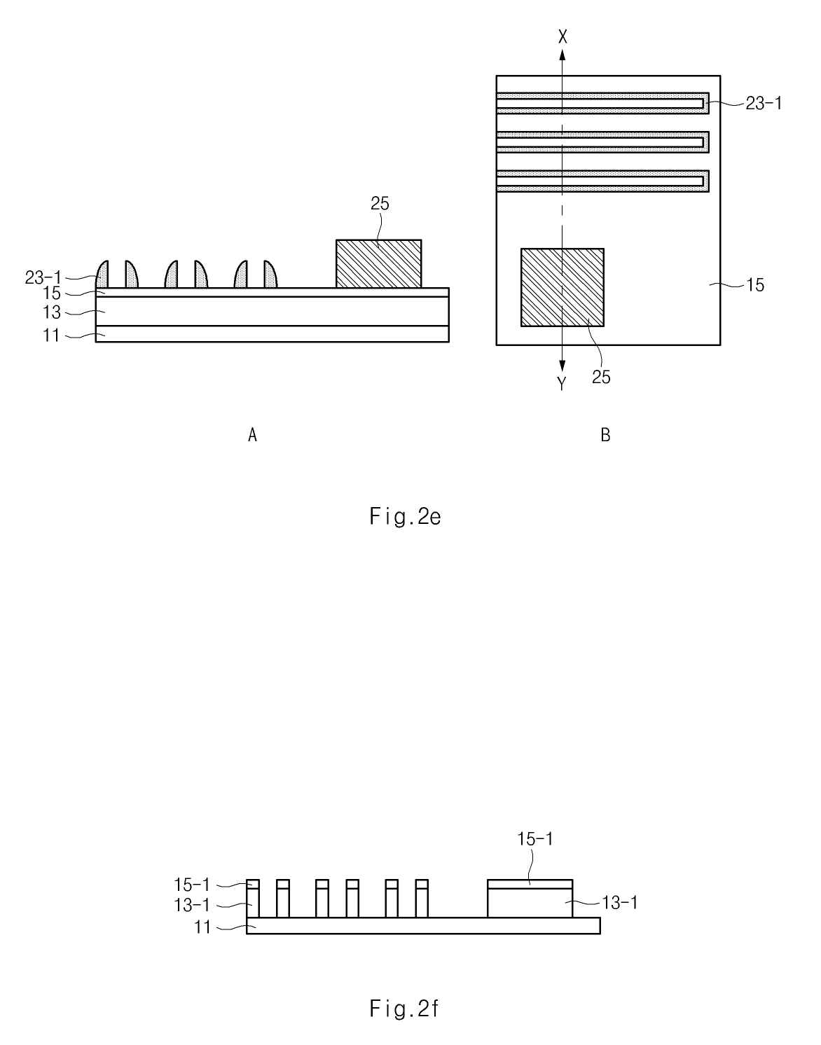

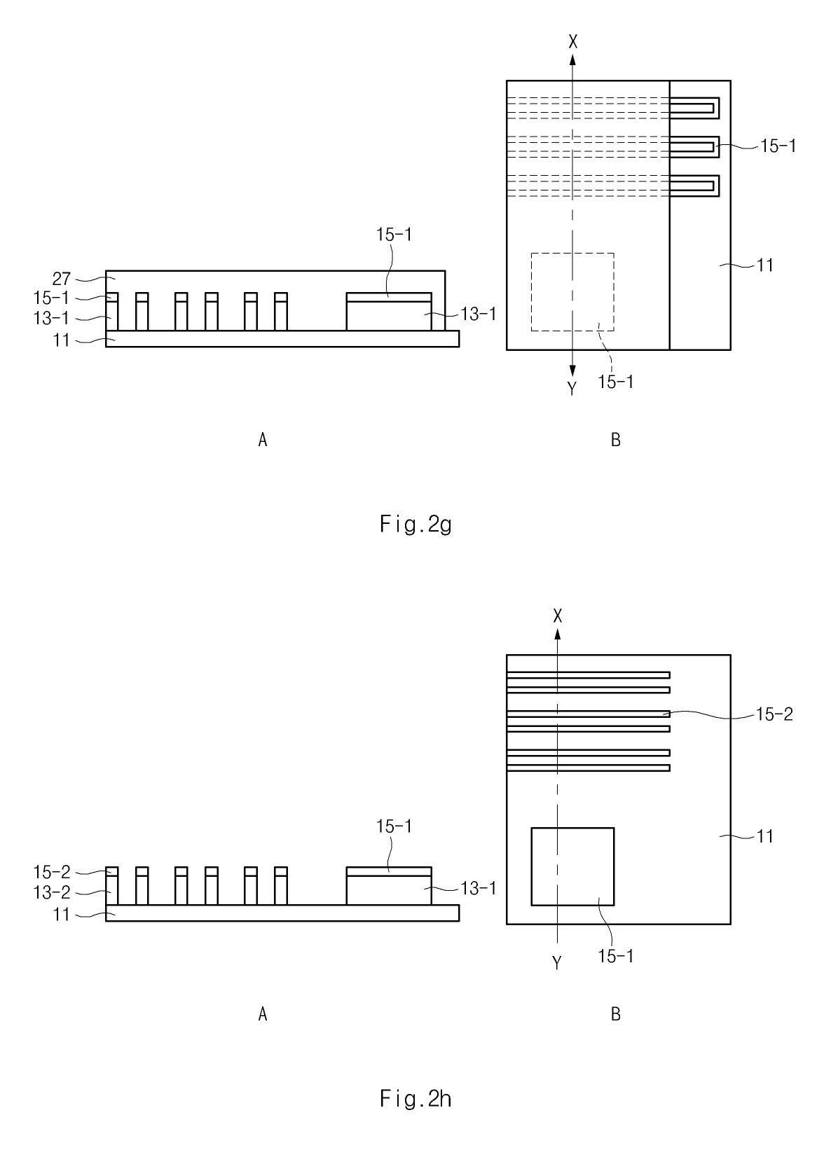

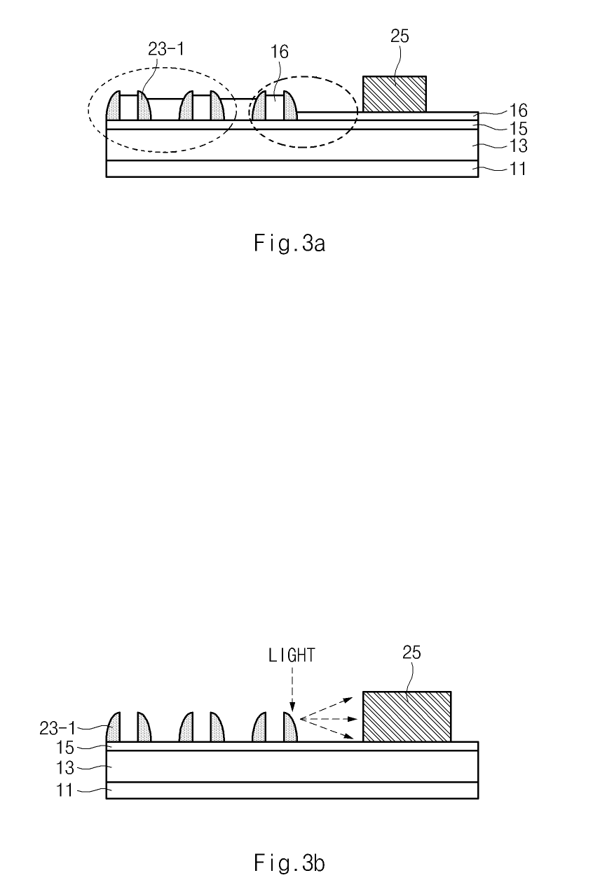

### DESCRIPTION OF SPECIFIC EMBODIMENTS

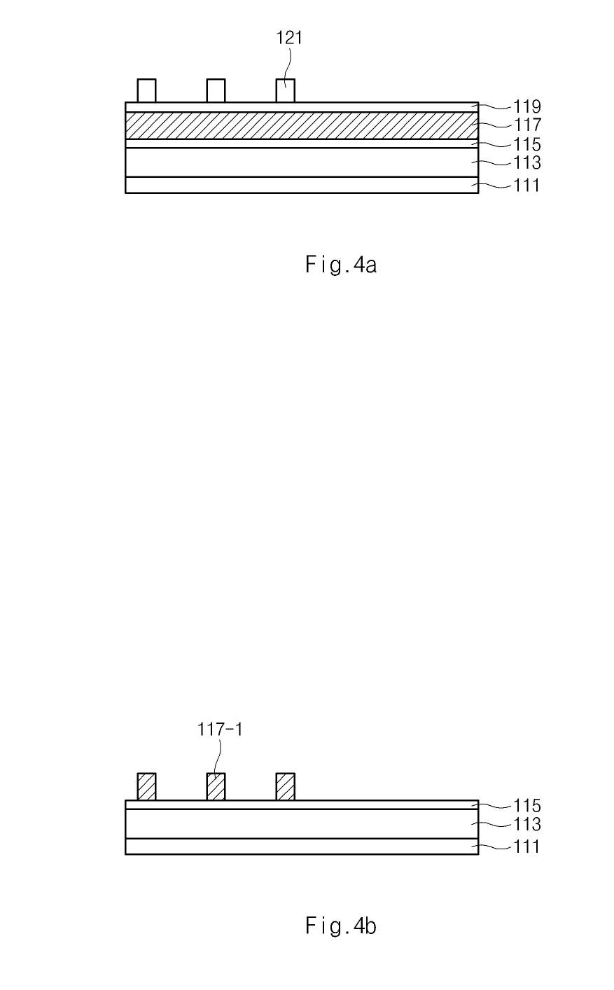

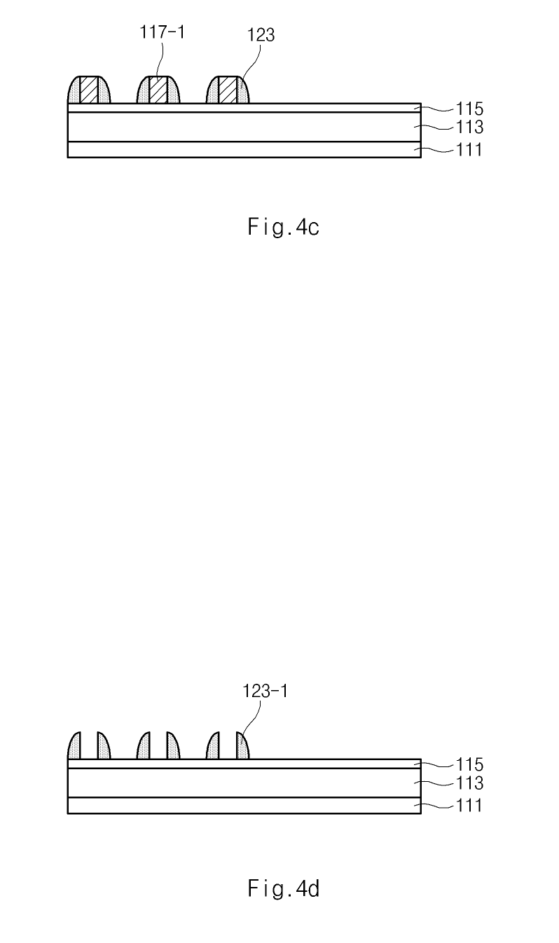

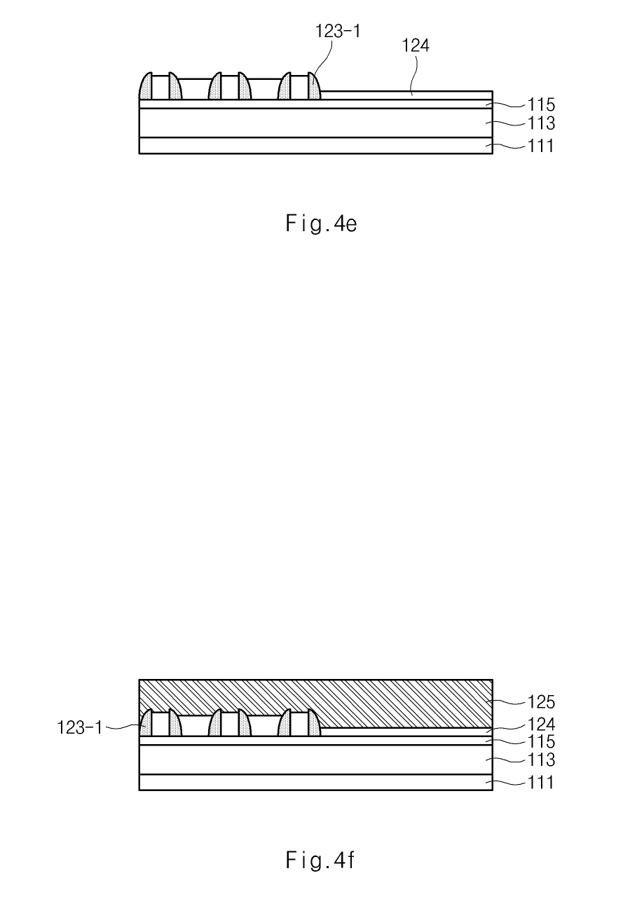

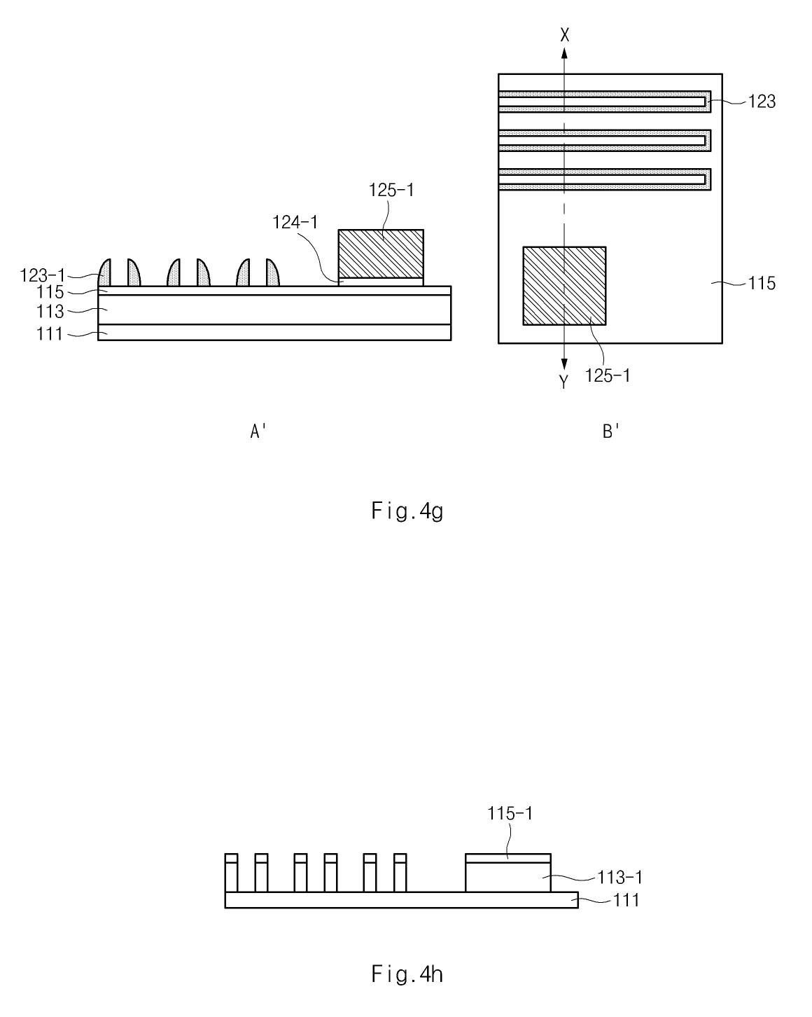

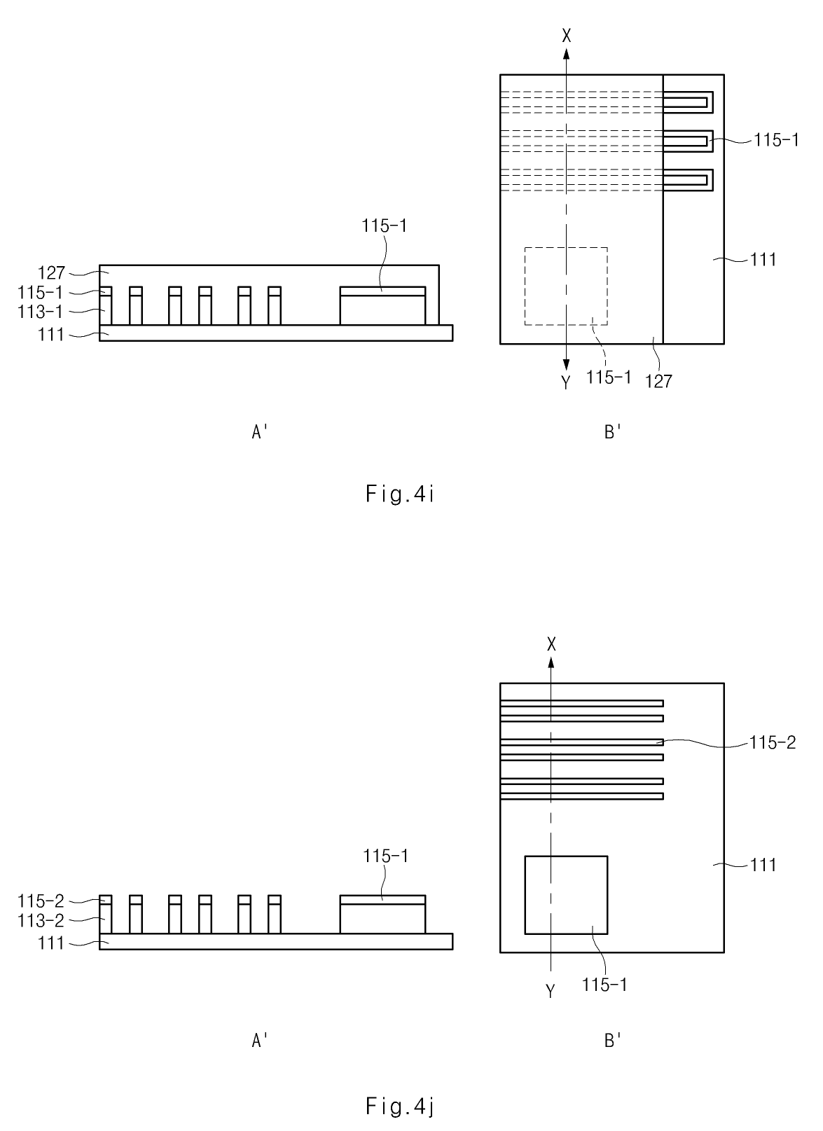

FIGS. 4a to 4i are diagrams illustrating a method for forming a pattern of a semiconductor according to an embodiment of the present invention.

Referring to FIG. 4a, an underlying layer 111 is formed over a substrate. The substrate may include an isolation film (ISO) (not shown) and the underlying layer 111 may include a dielectric film (not shown) [e.g., oxide film-nitride film-oxide film (ONO)], a gate polysilicon layer (not shown), a tungsten conductive layer (not shown), a capping oxide film (not shown) and a gate mask film (not shown).

A polysilicon layer 113, a first nitride film 115 (i.e., a first mask film), an oxide film 117 (i.e., a second mask film) and a third mask film 119 are sequentially deposited over the underlying layer. The oxide film 117 is formed with TEOS. Since the oxide film 117 determines a spacer height in a spacer patterning process, the oxide film is required to have over a given height, ranging from about 1000 to 2000 Å.

In the case of the third mask film 119, when the oxide film 117 is etched using a photoresist pattern as an etching mask, a polysilicon layer can be used for the third mask film 119 to secure an etching selectivity.

After an organic antireflection film (not shown) and a photoresist film (not shown) are coated over the third mask film 119, a first photolithography process is performed on the photoresist film to form a first photoresist pattern 121.

The first photoresist pattern is formed to have a pitch double that of a device pitch. In the case of a 40 nm semiconductor device, when an etching bias is not considered, a photoresist pattern bar region is 40 nm, and a space region is 120 nm, which has a line to space ratio of 1:3.

Referring to FIG. 4b, the antireflection film (not shown) and the third mask film 119 are etched using the first photoresist pattern 121 as an etching mask to form a antireflection film pattern (not shown) and a third mask pattern (not shown). The oxide film 117 is etched using the first photoresist pattern 121, an antireflection pattern (not shown) and the third mask pattern (not shown) as etching masks to form an oxide film pattern 117-1.

Referring to FIG. 4c, a polysilicon film (not shown) is deposited over the substrate including an oxide film pattern 117-1, and etched to form a spacer 123 at sidewalls of the oxide film pattern 117-1.

Referring to FIG. 4d, the oxide film pattern 117-1 is removed by a wet etching process using a HF solution. As a result, a spacer pattern 123-1 is obtained. The spacer pattern 123-1 has an end portion connected in a “⊂” shape which connects the neighboring two spacer patterns. The first nitride film 115 is not damaged during the etching process due to its resistance to HF.

Referring to FIGS. 4e and 4f, a developable antireflection film 124 and a second photoresist film (not shown) are coated over the substrate including the spacer pattern 123-1. The antireflection film is water-soluble in a developing solution.

Any antireflection films that are water-soluble in an alkali developing solution can be used to improve an adhesive force of the photoresist film to the substrate.

Specifically, the antireflection film 124 is formed by (i) spin-coating an antireflection composition over the substrate; and (ii) baking the antireflection composition to form a cured antireflection film. The antireflection composition may include a polymer for an antireflection film, cross-linking agents, and organic solvents.

The polymer for an antireflection film 124 includes an acrylate type polymer having a carboxyl group, a methacrylate type polymer having a carboxyl group and a norbornene type polymer having a carboxyl group or its mixture. The cross-linking agents include acrolein dimethylacetal, acrolein diethylacetal, melamine or its mixture. And an organic solvent may include propyleneglycol methyletheracetate (PGMEA), propyleneglycol monomethylether (PGME), ethyl lactate, cyclohexanone, γ-butyrolactone, n-butanol, 2-butanol, 1-pentanol, 2-pentanol or its mixture.

The baking process is performed at 100˜250° C. The antireflection film 124 is formed to have a thickness of 10˜30% of the whole photoresist pattern thickness.

The antireflection film 124 is coated higher in a region where spacer pattern is more dense than a region where a spacer pattern has a low density, e.g., edge region. While the solvent is vaporized in the subsequent baking process, a cross-linkage is formed between polymers in the antireflection composition so that the antireflection film is cured. As a result, the cured antireflection film is not dissolved in an edge bead removal (EBR) solution or a photoresist solution.

Referring to FIG. 4g (A′), a second photolithography process is performed on the first photoresist film 125 to form a stacked pattern including an antireflection pattern 124-1 and a second photoresist pattern 125-1 (to be used as an etching mask for forming a pad pattern). As shown in (B′) of FIG. 4f, the stack pattern is formed in a peripheral region of the spacer pattern 123-1. A photoresist pattern (not shown) for a SSL or a DSL is formed at the same time when forming a pad mask.

The photolithography process includes performing an exposing process using light sources such as KrF, ArF and EUV. For example, the photolithography process may use an ArF immersion scanner employing an exposure energy of 100 mJ/cm² and a developing process using an alkali aqueous solution.

In the photoresist film patterning exposing process, the cross-linked polymer in the cured antireflection film reacts with an acid generated from the photoresist film. This causes the cross-linkage to be broken during the baking process, so that the antireflection film can be dissolved in a developing solution. The exposed photoresist film is removed in a subsequent (photoresist pattern) developing process. The unexposed antireflection film disposed in the lower portion of the photoresist pattern is not removed.

Referring to FIG. 4h, the polysilicon layer 113 and the nitride film 115 (i.e., first mask film) are etched with the spacer pattern 123-1 and a stacked pattern including the antireflection pattern 124-1 and photoresist pattern 125 as etching masks until the underlying layer 111 is exposed. This forms a mask pattern for a pad pattern and a first mask pattern for a word line including a stacked pattern of a polysilicon pattern 113-1 and a first mask nitride pattern 115-1. The first mask pattern for a word line has an end portion in a “⊂” shape corresponding to the shape of the spacer pattern.

Referring to FIG. 4i, a third photoresist film (not shown) is coated over the substrate including the first mask pattern for a word line and the mask pattern for a pad pattern. A third photolithography process is performed on the third photoresist film to form a third photoresist pattern 127. As shown in (B′) of FIG. 4i, the third photoresist pattern 127 does not cover the “⊂” shaped end portion of the pattern for a word line.

Referring to FIG. 4j, the “⊂” shaped end portion of the pattern for a word line is etched using the third photoresist pattern 127 as an etching mask, thereby obtaining a second mask pattern for a word line that includes a polysilicon pattern 113-2 and a first mask nitride pattern 115-2 whose end portions are separated from the neighboring second mask pattern.

The step of etching the end portion of the first mask pattern for a word line is performed using a hydrofluorocarbon gas including CF₄ and CHF₃.

The lower underlying layer 111 is etched using the second mask pattern for a word line and the mask pattern for a pad pattern, thereby obtaining a control gate pattern of a NAND flash memory device.

As described above, the method of the present invention enables formation of the photoresist pattern for a pad pattern having an excellent profile.

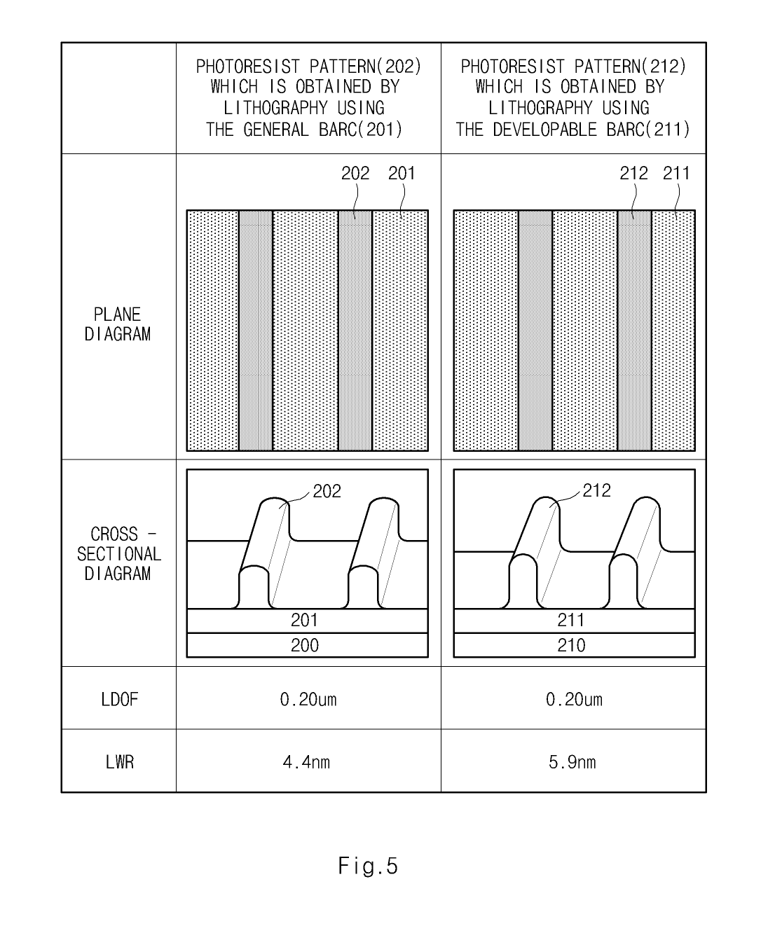

Meanwhile, the photoresist pattern 212 obtained by the lithography process using the developable antireflection film 211 of the present invention has a similar value of the depth of focus to that of the photoresist pattern 202 obtained by the lithography process using the conventional antireflection film 201. Here, 200 and 210 are an underlying layer (see FIG. 5). Therefore, when SSL or DSL of a 2×100 nm NAND flash memory device is formed, the developable antireflection film can be used in the lithography process.

The above embodiments of the disclosure are illustrative and not limitative. Various alternatives and equivalents are possible. The invention is not limited by the type of deposition, etching polishing, and patterning steps describe herein. Nor is the invention limited to any specific type of semiconductor device. For example, the disclosure may be implemented in a dynamic random access memory (DRAM) device or non volatile memory device. Other additions, subtractions, or modifications are obvious in view of the present disclosure and are intended to fall within the scope of the appended claims.

What is claimed is:

1. A method for forming a pattern of a semiconductor device, the method comprising:
providing a substrate having a cell region and a peripheral circuit region, the substrate having an underlying layer overlying the cell region and the peripheral region;
forming a first mask film over the underlying layer and forming a second mask film over the first mask film;
patterning the second mask film to form a second mask pattern over the first mask film of the cell region;
forming a spacer at sidewalls of the second mask pattern;
removing the second mask pattern;
coating an antireflection film over the cell region and the peripheral circuit region;
forming a photoresist film over the spacer and the antireflection film;
pattering the antireflection film and the photoresist film to form stack patterns including an antireflection film pattern and a photoresist pattern on the peripheral circuit region; and
etching the first mask film using the spacer of the cell region and the stack pattern of the peripheral circuit region as etching masks to form a first mask pattern for word line on the cell region and a first mask pattern for a pad pattern on the peripheral circuit region.

2. The method of claim 1, wherein the antireflection film is formed using material that can be dissolved in an alkali developing solution.

3. The method of claim 1, wherein the photoresist is formed using material that generates acid when exposed to light.

4. The method according to claim 1, wherein a pitch of the second mask pattern is twice wider than a device pitch.

5. The method according to claim 1, wherein the removing-the-second-mask-pattern includes performing a wet process using hydrofluoric acid (HF).

6. The method according to claim 1, wherein the antireflection film is formed using an antireflection composition comprising a polymer for an antireflection film, a cross-linking agent and an organic solvent.

7. The method according to claim 6, wherein the polymer for an antireflection film comprises one or more compounds selected from the group consisting of an acrylate type polymer having a carboxyl group, a methacrylate type polymer having a carboxyl group and a norbornene type polymer having a carboxyl group so that the cross-linking can be broken in the presence of an acid.

8. The method according to claim 6, wherein the cross-linking agent comprises one or more compound selected from the group consisting of an acrolein dimethylacetal, an acrolein diethylacetal and a melamine.

9. The method according to claim 6, wherein the organic solvent comprises one or more selected from the group consisting of propyleneglycol methyletheracetate (PGMEA), propyleneglycol monomethylether (PGME), ethyl lactate, cyclohexanone, γ-butyrolactone, n-butanol, 2-butanol, 1-pentanol and 2-pentanol.

10. The method according to claim 1, wherein the antireflection film is not dissolved in a wafer edge bead removal solution and a photoresist solution.

11. The method according to claim 1, wherein the-pattering-the-antireflection-film-and-the-photoresist-film includes exposing the photoresist film with light sources; and developing the photoresist film with an alkali aqueous solution.

12. The method according to claim 11, wherein the antireflection film and the photoresist film are dissolved in the alkali aqueous solution during the developing process.

13. A method for forming a pattern for a semiconductor device, the method comprising
providing a substrate; and
forming a word line pattern over the substrate using a double exposing and etching technology,
wherein the double exposing and etching technology includes an antireflection coating process that employs an antireflection composition comprising a polymer for an antireflection film, a cross-linking agent and an organic solvent.

14. A method for forming a pattern of a semiconductor device, the method comprising:
providing a substrate having a cell region and a peripheral region, the substrate having an underlying layer overlying the cell region and the peripheral region;
forming a plurality of spacers in the cell region overlying the underlying layer;
forming an antireflection film over the cell region and the peripheral region;
forming a photoresist film over the spacers and the antireflection film; and
pattering the antireflection film and the photoresist film to form stack patterns including an antireflection film pattern and a photoresist pattern on the peripheral region,
wherein the spacers are used to form word lines on the cell region and the stack pattern is used to form a pad pattern on the peripheral region.

15. The method of claim 14, wherein the antireflection film is formed using an antireflection composition comprising a polymer for an antireflection film, a cross-linking agent and an organic solvent.

16. The method of claim 15, wherein the polymer for the antireflection film comprises one or more compounds selected from the group consisting of an acrylate type polymer having a carboxyl group, a methacrylate type polymer having a carboxyl group and a norbornene type polymer having a carboxyl group so that the cross-linking can be broken in the presence of an acid.

17. The method of claim 15, wherein the cross-linking agent comprises one or more compound selected from the group consisting of an acrolein dimethylacetal, an acrolein diethylacetal and a melamine.

18. The method of claim 14, wherein the spacers are formed over a mask film that is provided over the underlying layer.
